(19) United States
(12) Patent Application Publication
(10) Pub. No.: US 2025/0191978 A1
(43) Pub. Date: Jun. 12, 2025

(54) PATTERN INSPECTION METHOD, METHOD FOR MANUFACTURING RESIST PATTERN, TARGET SUBSTRATE SELECTION METHOD, AND METHOD FOR MANUFACTURING TARGET SUBSTRATE

(71) Applicant: Resonac Corporation, Tokyo (JP)

(72) Inventors: Tetsuya KATO, Tokyo (JP); Kensuke YOSHIHARA, Tokyo (JP); Yosuke KAGUCHI, Tokyo (JP); Natsuki TODA, Tokyo (JP); Masakazu KUME, Tokyo (JP); Hiroshi ONO, Tokyo (JP)

(21) Appl. No.: 18/841,160

(22) PCT Filed: Feb. 20, 2023
(86) PCT No.: PCT/JP2023/006062

§ 371 Date: Aug. 23, 2024

(30) Foreign Application Priority Data
Feb. 28, 2022 (WO) PCT/JP2022/008187

(51) Int. Cl. H01L 21/66; G01N 21/64; H01L 21/48

(52) U.S. Cl. CPC H01L 22/12; G01N 21/6489; H01L 21/4857; H01L 21/486; H01L 22/26

(57) ABSTRACT

A pattern inspection method includes: a coordinate measuring step for measuring the coordinates of a contour of a pattern on a target substrate, which is either a printed circuit board or a semiconductor package substrate for mounting of semiconductor elements on which the pattern is formed; and an inspection step for inspecting the pattern based on the coordinates. A target substrate selection method includes: a coordinate measuring step for measuring the coordinates of a contour of a pattern on a target substrate, which is either a printed circuit board or a semiconductor package substrate for mounting of semiconductor elements on which the pattern is formed; an inspection step for inspecting the pattern based on the measured coordinates; and an evaluation step for evaluating the pattern based on an inspection result in the inspection step.

### TECHNICAL FIELD

The present disclosure relates to a pattern inspection method for inspecting a pattern, which is either a resist pattern or a conductor pattern formed on a target substrate that is either a printed circuit board or a semiconductor package substrate for mounting of semiconductor elements, a method for manufacturing a resist pattern formed on a target substrate, a target substrate selection method, and a method for manufacturing a target substrate.

### BACKGROUND ART

In the manufacture of semiconductor elements, resist patterns or conductor patterns formed on silicon wafers, which are substrates of semiconductor elements, are inspected using a scanning microscope (see, for example, Patent Literatures 1 and 2). In the inspection of the resist pattern or the conductor pattern formed on the silicon wafer, a roughness index of the resist pattern or the conductor pattern is calculated by pattern observation using a scanning microscope.

On the other hand, resist patterns or conductor patterns are also formed on a printed circuit board or a semiconductor package substrate for mounting of semiconductor elements (see, for example, Patent Literature 3). However, the pitch of resist patterns or conductor patterns formed on the semiconductor package substrate or the printed circuit board is much larger than the pitch of resist patterns or conductor patterns formed on the substrate of the semiconductor element. For this reason, the effect of the roughness of resist patterns or conductor patterns formed on the semiconductor package substrate or the printed circuit board on the electrical characteristics is much smaller than the effect of the roughness of resist patterns or conductor patterns formed on the substrate of the semiconductor element on the electrical characteristics. The electrical characteristics include a biased highly accelerated stress test (insulation reliability), transmission loss, and the like. For this reason, conventionally, the roughness of resist patterns or conductor patterns formed on the semiconductor package substrate or the printed circuit board has not been inspected, or has only been inspected qualitatively using a microscope or visually.

### CITATION LIST

### Patent Literature

Patent Literature 1: Japanese Unexamined Patent Publication No. 2006-215020
Patent Literature 2: Japanese Unexamined Patent Publication No. 2004-251743
Patent Literature 3: Japanese Unexamined Patent Publication No. 2005-207802

### SUMMARY OF INVENTION

### Technical Problem

In recent years, there has been a demand for finer conductor patterns in semiconductor package substrates or printed circuit boards. In addition, along with the demand for finer conductor patterns, there is also a demand for finer resist patterns for forming the conductor patterns. The finer resist patterns or conductor patterns may cause defects such as degradation of the electrical characteristics of a semiconductor package to be manufactured.

Here, if it is possible to inspect resist patterns or conductor patterns formed on the semiconductor package substrate or the printed circuit board, such defects can be found at an earlier stage in the manufacture of semiconductor packages and the like. In addition, by evaluating the yield of resist pattern formation or conductor pattern formation on the semiconductor package substrate or the printed circuit board, it is possible to improve the resist pattern formation or the conductor pattern formation on the semiconductor package substrate or the printed circuit board.

However, as described above, conventionally, resist patterns or conductor patterns formed on the semiconductor package substrate or the printed circuit board have not been inspected, or have only been inspected qualitatively using a microscope or visually. In addition, since the semiconductor package substrate or the printed circuit board is different from the semiconductor element in terms of the width of the inspection range, the uniformity of the thickness of an inspection target, and the distortion and warpage of a substrate to be inspected, it has conventionally been difficult or impossible to inspect resist patterns or conductor patterns formed on the semiconductor package substrate or the printed circuit board. For this reason, conventionally, when resist patterns or conductor patterns formed on the semiconductor package substrate or the printed circuit board are made finer, it has not been clear at all how to evaluate the resist patterns or the conductor patterns formed on the semiconductor package substrate or the printed circuit board.

Therefore, an object of the present disclosure is to provide a pattern inspection method capable of evaluating a pattern even if the pattern, which is either a resist pattern or a conductor pattern formed on a target substrate that is either a semiconductor package substrate or a printed circuit board, is made finer, a resist pattern manufacturing method, a target substrate selection method, and a target substrate manufacturing method.

### Solution to Problem

As a result of thorough investigation into the above-mentioned problem, the inventors have found that it is possible to measure the coordinates of the contour of a pattern formed on a target substrate and evaluate the pattern based on the measurement results. The present disclosure has been made based on this finding.

[1] A pattern inspection method of the present disclosure is a pattern inspection method for inspecting a pattern, which is either a resist pattern or a conductor pattern formed on a target substrate that is either a printed circuit board or a semiconductor package substrate for mounting of semiconductor elements. This pattern inspection method includes a coordinate measuring step for measuring coordinates of a contour of the pattern and an inspection step for inspecting the pattern based on the measured coordinates.

In this pattern inspection method, the coordinates of the contour of the pattern formed on the target substrate are measured, and the pattern is inspected based on the measured coordinates. For this reason, even if the pattern formed on the target substrate is made finer, the pattern can be evaluated. In addition, the pattern can be evaluated with higher accuracy than in the case of visual inspection.

[2] In the pattern inspection method according to [1], in the inspection step, as the inspection of the pattern, a roughness of the pattern may be calculated based on the measured coordinates. In this pattern inspection method, the roughness of the pattern is calculated based on the measured coordinates of the contour. Therefore, it is possible to appropriately evaluate the formation state of the pattern.

[3] In the pattern inspection method according to [1] or [2], in the inspection step, as the inspection of the pattern, a variation in a contour of the pattern may be calculated based on the measured coordinates. In this pattern inspection method, as the inspection of the pattern, the variation in the contour of the pattern is calculated based on the measured coordinates of the contour. Therefore, it is possible to appropriately evaluate the formation state of the pattern.

[4] In the pattern inspection method according to [1] or [2], in the inspection step, as the inspection of the pattern, a line width of the pattern and a variation in the line width may be calculated based on the measured coordinates. In this pattern inspection method, as the inspection of the pattern, the line width of the pattern and the variation in the line width are calculated based on the measured coordinates of the contour. Therefore, it is possible to appropriately evaluate the formation state of the pattern.

[5] In the pattern inspection method according to any one of [1] to [4], in the inspection step, as the inspection of the pattern, the measured coordinates may be compared with pattern data for forming the pattern. In this pattern inspection method, as the inspection of the pattern, the measured coordinates of the contour is compared with pattern data for forming the pattern. Therefore, it is possible to evaluate the formation state of the pattern with high accuracy.

[6] In the pattern inspection method according to any one of [1] to [5], the target substrate may contain an inorganic component containing at least one of silica filler and glass cloth and an organic component containing at least one of maleimide resin, bismaleimide-triazine resin, epoxy resin, phenolic resin, cyanate resin, isocyanate resin, benzoxazine resin, oxetane resin, amino resin, unsaturated polyester resin, allyl resin, dicyclopentadiene resin, triazine resin, melamine resin, and polyethylene terephthalate resin. In this pattern inspection method, the target substrate contains an inorganic component containing at least one of silica filler and glass cloth, which are not used in substrates of semiconductor elements, and an organic component containing at least one of maleimide resin, bismaleimide-triazine resin, epoxy resin, phenolic resin, cyanate resin, isocyanate resin, benzoxazine resin, oxetane resin, amino resin, unsaturated polyester resin, allyl resin, dicyclopentadiene resin, triazine resin, melamine resin, and polyethylene terephthalate resin. For this reason, compared with the case of inspecting the pattern formed on the substrate of the semiconductor element, there are problems and difficulties such as distortion and warpage of the inspection target. However, by providing the above-described coordinate measuring step and inspection step, the pattern formed on the target substrate can be evaluated.

[7] In the pattern inspection method according to any one of [1] to [6], the target substrate may have at least one of a core layer and a build-up layer. In this pattern inspection method, the target substrate includes at least one of the core layer and the build-up layer, unlike the structure of the substrate of the semiconductor element. For this reason, compared with the case of inspecting the pattern formed on the substrate of the semiconductor element, there are problems and difficulties such as distortion and warpage of the inspection target. However, by providing the above-described coordinate measuring step and inspection step, the pattern formed on the target substrate can be evaluated.

[8] In the pattern inspection method according to any one of [1] to [7], a thickness of the target substrate may be 50 μm or more and 3000 μm or less. In this pattern inspection method, the thickness of the target substrate is 50 μm or more and 3000 μm or less, which is different from the thickness of the substrate of the semiconductor element. For this reason, compared with the case of inspecting the pattern formed on the substrate of the semiconductor element, there are problems and difficulties such as the focal position of the inspection target changing greatly depending on the observation point due to distortion and warpage of the inspection target and variations in the thickness of the inspection target, making difficult for the resist pattern and the conductor in focus. However, by providing the above-described coordinate measuring step and inspection step, the pattern formed on the target substrate can be evaluated.

[9] In the pattern inspection method according to any one of [1] to [8], the pattern may be the resist pattern, and the resist pattern may contain a binder polymer having a carboxyl group, a radical polymerizable compound having an ethylenically unsaturated bond, and a photoradical polymerization initiator. In this pattern inspection method, the resist pattern formed on the target substrate contains a binder polymer having a carboxyl group, a radical polymerizable compound having an ethylenically unsaturated bond, and a photoradical polymerization initiator, unlike the resist pattern formed on the substrate of the semiconductor element. The substrate of the semiconductor element has no support and is thin. Therefore, when a binder polymer having a carboxyl group, a radical polymerizable compound having an ethylenically unsaturated bond, and a photoradical polymerization initiator are used in manufacturing the substrate of the semiconductor element, there are problems and difficulties such as the effect of oxygen in the exposure atmosphere inhibiting the curing of the resin, making it difficult to form a pattern. However, when the resist pattern is formed on the target substrate, even if the resist pattern contains a binder polymer having a carboxyl group, a radical polymerizable compound having an ethylenically unsaturated bond, and a photoradical polymerization initiator, the resist pattern can be formed on the target substrate. Therefore, by providing the above-described coordinate measuring step and inspection step, the resist pattern formed on the target substrate can be evaluated.

[10] In the pattern inspection method according to any one of [1] to [9], the pattern may be the resist pattern, a resin film may be provided on the resist pattern, and in the coordinate measuring step, the coordinates of the contour of the pattern may be measured through the resin film. In this pattern inspection method, a resin film, which is not provided on the resist pattern formed on the substrate of the semiconductor element, is provided on the resist pattern, and the coordinates of the contour of the pattern are measured through the resin film. For this reason, compared with the case of inspecting the resist pattern formed on the substrate of the semiconductor element, there are problems and difficulties involved in inspecting the resist pattern through a resin film. However, by providing the above-described coordinate measuring step and inspection step, the resist pattern formed on the target substrate can be evaluated.

[11] In the pattern inspection method according to any one of [1] to [10], the pattern may be the resist pattern, and a thickness of the resist pattern may be 3 μm or more and 200 μm or less. In this pattern inspection method, the resist pattern formed on the target substrate is a pattern having a different thickness from the resist pattern formed on the substrate of the semiconductor element. For this reason, compared with the case of inspecting the resist pattern formed on the substrate of the semiconductor element, there are problems and difficulties such as the detection contrast between the resist pattern and the substrate being likely to be low. However, by providing the above-described coordinate measuring step and inspection step, the resist pattern formed on the target substrate can be evaluated.

[12] In the pattern inspection method according to any one of [1] to [11], in the coordinate measuring step, the coordinates of the contour of the pattern may be measured based on reflected light from the target substrate. In a semiconductor element, its substrate is formed of silicon, and a resist pattern is formed on the silicon oxide film or the silicon nitride film. For this reason, even if reflected light from the substrate of the semiconductor element is detected, it is not possible to obtain, from the reflected light, a contrast between the substrate (silicon oxide film or silicon nitride film) and the resist pattern to the extent that the boundary between the substrate and the resist pattern can be identified. On the other hand, in the target substrate, the resist pattern is formed on the conductor layer formed of copper or the like. For this reason, when reflected light from the target substrate is detected, it is possible to obtain, from the reflected light, a contrast between the substrate (conductor layer) and the resist pattern to the extent that the boundary between the substrate and the resist pattern can be identified. Therefore, in this pattern inspection method, the coordinates of the contour of the pattern are measured based on the reflected light from the target substrate. As a result, it is possible to appropriately measure the coordinates of the contour of the pattern with high accuracy.

[13] In the pattern inspection method according to any one of [1] to [11], in the coordinate measuring step, the coordinates of the contour of the pattern may be measured based on fluorescent light from the target substrate. In a semiconductor element, its substrate is formed of silicon, and a resist pattern is formed on the silicon oxide film or the silicon nitride film. For this reason, even if fluorescent light from the substrate of the semiconductor element is detected, it is not possible to obtain, from the fluorescent light, a contrast between the substrate (silicon oxide film or silicon nitride film) and the resist pattern to the extent that the boundary between the substrate and the resist pattern can be identified. On the other hand, in the target substrate, the resist pattern is formed on the conductor layer formed of copper or the like. For this reason, when fluorescent light from the target substrate is detected, it is possible to obtain, from the fluorescent light, a contrast between the substrate (conductor layer) and the resist pattern to the extent that the boundary between the substrate and the resist pattern can be identified. Therefore, in this pattern inspection method, the coordinates of the contour of the pattern are measured based on the fluorescent light from the target substrate. As a result, it is possible to appropriately measure the coordinates of the contour of the pattern with high accuracy.

[14] In the pattern inspection method according to any one of [1] to [11], in the coordinate measuring step, the coordinates of the contour of the pattern may be measured based on an electron beam from the target substrate. In this pattern inspection method, the coordinates of the contour of the pattern are measured based on the electron beam from the target substrate. Therefore, it is possible to appropriately measure the coordinates of the contour of the pattern with high accuracy.

[15] A resist pattern manufacturing method of the present disclosure includes: a resist pattern forming step for forming a resist pattern on a target substrate, which is either a printed circuit board or a semiconductor package substrate for mounting of semiconductor elements; a coordinate measuring step for measuring coordinates of a contour of the resist pattern after the resist pattern forming step; and an inspection step for inspecting the resist pattern based on the coordinates.

In this resist pattern manufacturing method, after the resist pattern is formed on the target substrate, the coordinates of the contour of the resist pattern formed on the target substrate are measured, and the resist pattern is inspected based on the measured coordinates. Therefore, even if the resist pattern formed on the target substrate is made finer, the resist pattern can be evaluated. As a result, it is possible to manufacture the resist pattern with a small degree of roughness.

[16] In the resist pattern manufacturing method according to [15], in the coordinate measuring step, the coordinates of the contour of the resist pattern may be measured based on reflected light from the target substrate, fluorescent light from the target substrate, or an electron beam from the target substrate. In this resist pattern manufacturing method, the coordinates of the contour of the resist pattern are measured based on the reflected light from the target substrate, the fluorescent light from the target substrate, or the electron beam from the target substrate. Therefore, it is possible to appropriately measure the coordinates of the contour of the pattern with high accuracy.

[18] A target substrate selection method of the present disclosure is a target substrate selection method for selecting a target substrate, which is either a printed circuit board or a semiconductor package substrate for mounting of semiconductor elements. This target substrate selection method includes: a coordinate measuring step for measuring coordinates of a contour of a pattern formed on the target substrate; an inspection step for inspecting the pattern based on the measured coordinates; and an evaluation step for evaluating the pattern based on an inspection result in the inspection step.

In this target substrate selection method, the coordinates of the contour of the pattern, which is either a resist pattern or a conductor pattern formed on the target substrate, are measured, the pattern is inspected based on the measured coordinates, and the pattern is evaluated based on the inspection result. Therefore, the pattern can be evaluated with higher accuracy than in the case of visual inspection.

[18] In the target substrate selection method according to [17], in the inspection step, as the inspection of the pattern, a roughness of the pattern may be calculated based on the measured coordinates, and in the evaluation step, the pattern may be evaluated based on the roughness of the pattern. In this target substrate selection method, since the pattern is evaluated based on the roughness of the pattern calculated based on the measured coordinates of the contour, the formation state of the pattern can be appropriately evaluated.

[19] In the target substrate selection method according to [17] or [18], in the inspection step, as the inspection of the pattern, a variation in the contour may be calculated based on the measured coordinates, and in the evaluation step, the pattern may be evaluated based on the variation in the contour. In this target substrate selection method, since the pattern is evaluated based on the variation in the contour calculated based on the measured coordinates of the contour, the formation state of the pattern can be appropriately evaluated.

[20] In the target substrate selection method according to any one of [17] to [19], in the inspection step, as the inspection of the pattern, a line width of the pattern and a variation in the line width may be calculated based on the measured coordinates, and in the evaluation step, the pattern may be evaluated based on the calculated variation in the line width. In this target substrate selection method, since the pattern is evaluated based on the variation in the line width calculated based on the measured coordinates of the contour, the formation state of the pattern can be appropriately evaluated.

[21] In the target substrate selection method according to any one of [17] to [20], in the inspection step, as the inspection of the pattern, the measured coordinates may be compared with pattern data for forming the pattern, and in the evaluation step, the pattern may be evaluated based on a result of comparison between the measured coordinates and the pattern data. In this target substrate selection method, since the pattern is evaluated based on the result of comparison between the measured coordinates of the contour and the pattern data for forming the pattern, the formation state of the pattern can be appropriately evaluated.

[22] In the target substrate selection method according to any one of [17] to [21], in the coordinate measuring step, the coordinates of the contour of the pattern may be measured based on reflected light from the target substrate, fluorescent light from the target substrate, or an electron beam from the target substrate. In this target substrate selection method, since the coordinates of the contour of the pattern are measured based on the reflected light from the target substrate, the fluorescent light from the target substrate, or the electron beam from the target substrate, it is possible to appropriately measure the coordinates of the contour of the pattern with high accuracy.

[23] A target substrate manufacturing method of the present disclosure includes a conductor pattern forming step for forming the conductor pattern by performing etching processing or plating processing on the target substrate on which the resist pattern is formed, the resist pattern satisfying criteria for the evaluation of the resist pattern in the target substrate selection method according to any one of [17] to [22].

In this target substrate manufacturing method, the conductor pattern is formed by performing etching processing or plating processing on the target substrate satisfying the criteria for the evaluation of the resist pattern in the target substrate selection method described above, among the target substrates on which the resist patterns are formed. Therefore, it is possible to suppress the occurrence of defects such as defective formation of the conductor pattern and degradation of the electrical characteristics of the manufactured semiconductor package.

### Advantageous Effects of Invention

According to the present disclosure, even if a pattern, which is either a resist pattern or a conductor pattern formed on a target substrate that is either a semiconductor package substrate or a printed circuit board, is made finer, it is possible to evaluate the pattern.

### BRIEF DESCRIPTION OF DRAWINGS

FIG. 1(a) is a schematic perspective view for explaining a photosensitive layer forming step in a resist pattern forming step, FIG. 1(b) is a schematic perspective view for explaining an exposure step in the resist pattern forming step, and FIG. 1(c) is a schematic perspective view for explaining a development step in the resist pattern forming step.

FIG. 2 is a schematic cross-sectional view showing an example of a target substrate.

FIG. 3 is a schematic cross-sectional view showing another example of the target substrate.

FIG. 4 is a schematic cross-sectional view showing another example of the target substrate.

FIG. 5 is a schematic cross-sectional view showing another example of the target substrate.

FIG. 6 is a schematic perspective view for explaining a coordinate measuring step.

FIG. 7 is a schematic plan view showing an enlarged part of a pattern formed on a target substrate.

FIGS. 8(a), 8(b), and 8(c) are schematic perspective views for explaining the formation of a conductor pattern.

FIG. 9 is a photograph of Example 1.

FIG. 10 is a plot diagram of the coordinates of the contour of a resist pattern in Example 1.

FIG. 11 is a diagram in which the plot diagram of FIG. 10 is superimposed on the photograph of FIG. 9 with a shift.

FIG. 12 is a table showing the evaluation of Examples 1 and 2.

### DESCRIPTION OF EMBODIMENTS

Hereinafter, a pattern inspection method, a resist pattern manufacturing method, a target substrate selection method, and a target substrate manufacturing method of the present disclosure will be described with reference to the drawings. In addition, the same or equivalent portions are denoted by the same reference numerals throughout the drawings. In addition, “A or B” may include either A or B, or may include both. In addition, either a printed circuit board or a semiconductor package substrate for mounting of semiconductor elements is referred to as a target substrate, and either a resist pattern or a conductor pattern is referred to as a pattern.

### [Pattern Inspection Method]

A pattern inspection method according to an embodiment is an pattern inspection method for inspecting a pattern, which is either a resist pattern or a conductor pattern formed on a target substrate, which is either a printed circuit board or a semiconductor package substrate for mounting of semiconductor elements. As the pattern inspection method, there are a resist pattern inspection method for inspecting a resist pattern and a conductor pattern inspection method for inspecting a conductor pattern.

### [Resist Pattern Inspection Method]

A resist pattern inspection method includes a coordinate measuring step for measuring the coordinates of the contour of a resist pattern formed on a target substrate and an inspection step for inspecting the resist pattern based on the coordinates measured in the coordinate measuring step. The resist pattern inspection method may include a resist pattern forming step for forming a resist pattern on the target substrate before the coordinate measuring step. In addition, the resist pattern inspection method may include other steps. In this specification, the term “step” includes not only an independent step but also a step whose intended effect is achieved even if the step cannot be clearly distinguished from other steps. The resist pattern can also be said to be a photocured product pattern of a photosensitive resin composition or a relief pattern.

### <Resist Pattern Forming Step>

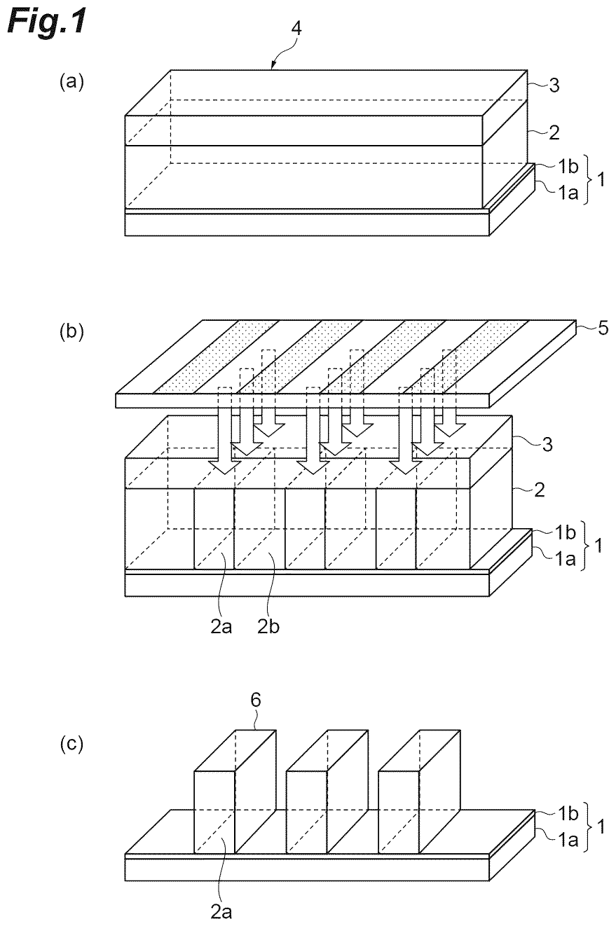

As shown in FIG. 1, a resist pattern forming step includes a photosensitive layer forming step in which a photosensitive layer 2 is stacked on a target substrate 1 (see FIG. 1(a)), an exposure step in which a predetermined portion of the photosensitive layer 2 is irradiated with actinic light to form a photocured portion (see FIG. 1(b)), and a development step in which an area of the photosensitive layer 2 other than the predetermined portion is removed from the target substrate 1 (see FIG. 1(c)). The resist pattern forming step may include other steps as necessary.

The target substrate 1 contains, for example, an inorganic component containing at least one of silica filler and glass cloth and an organic component containing at least one of maleimide resin, bismaleimide-triazine resin, epoxy resin, phenolic resin, cyanate resin, isocyanate resin, benzoxazine resin, oxetane resin, amino resin, unsaturated polyester resin, allyl resin, dicyclopentadiene resin, triazine resin, melamine resin, and polyethylene terephthalate resin.

The thickness of the target substrate 1 may be, for example, 50 μm or more, 100 μm or more, 300 μm or more, or 1000 μm or more. In addition, the thickness of the target substrate 1 may be, for example, 3000 μm or less, 2000 μm or less, or 1500 μm or less. The minimum and maximum values of the thickness of the target substrate 1 can be appropriately combined. For example, the thickness of the target substrate 1 may be 50 μm or more and 3000 μm or less, 100 μm or more and 2000 μm or less, 300 μm or more and 1500 μm or less, or 1000 μm or more and 3000 μm or less. The thickness of the target substrate 1 is the dimension of the target substrate 1 in a direction perpendicular to the main surface of the target substrate 1. In addition, the thickness of a substrate of a semiconductor element mounted on a semiconductor package substrate is, for example, 25 μm or more and 200 μm or less.

### (Photosensitive Layer Forming Step)

As shown in FIG. 1(a), in the photosensitive layer forming step, the photosensitive layer 2 and a support 3 are formed on the target substrate 1. In addition, it is not necessary to form the support 3 on the target substrate 1. In addition, when the support 3 is formed on the target substrate 1, the support 3 may be peeled from the target substrate 1 at any timing. The target substrate 1 includes, for example, an insulating layer 1a and a conductor layer 1b formed on the insulating layer 1a. The insulating layer 1a is, for example, a core material, a build-up material, or polyethylene terephthalate (PET).

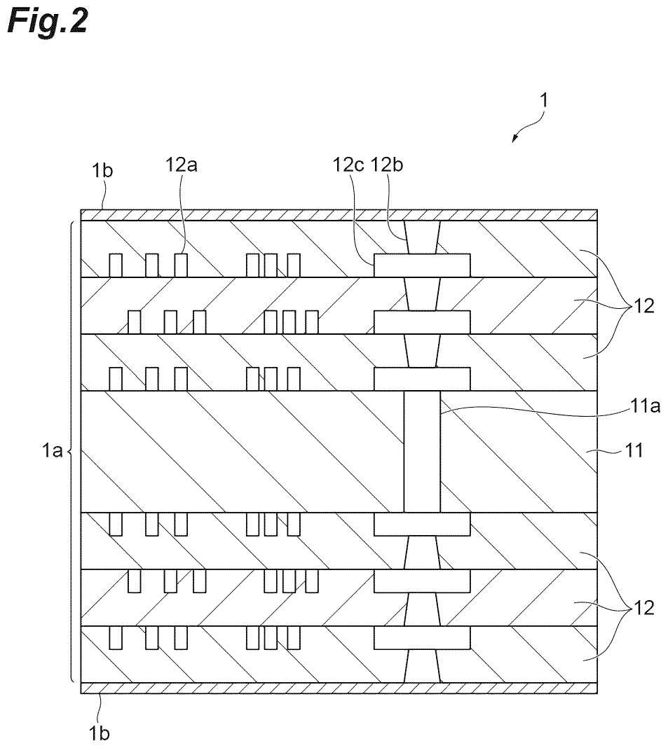

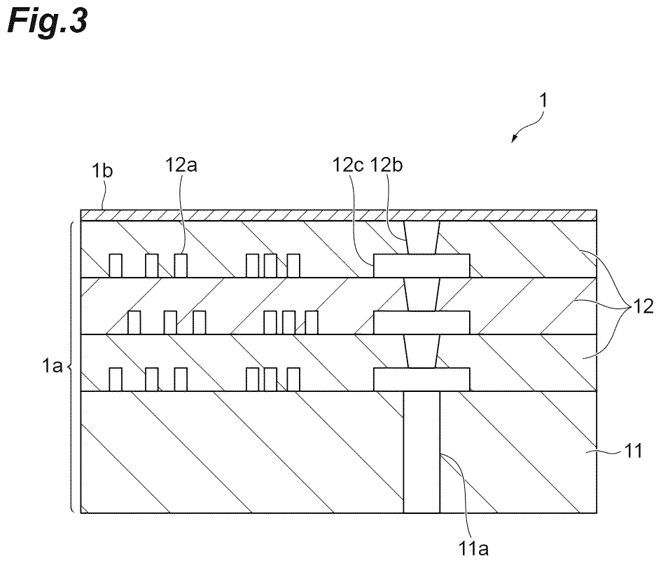

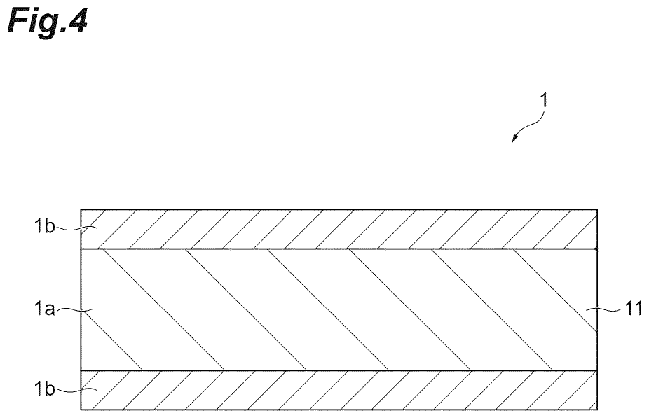

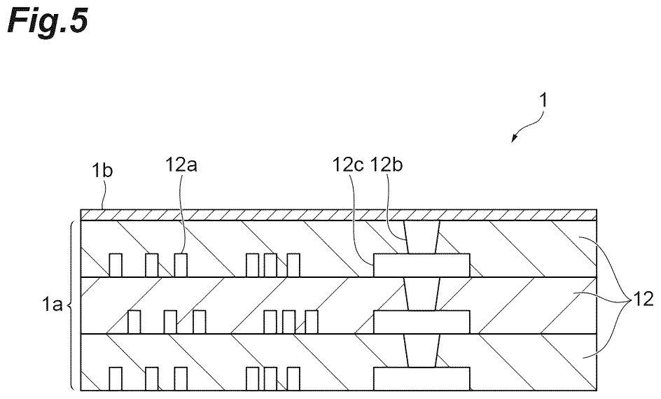

The insulating layer 1a may be formed by, for example, a core layer 11 and a pair of build-up layers 12 formed on both surfaces of the core layer 11, as shown in FIG. 2. Alternatively, the insulating layer 1a may be formed by the core layer 11 and the build-up layer 12 formed on one surface of the core layer 11, as shown in FIG. 3. Alternatively, the insulating layer 1a may be formed by only the core layer 11 without any build-up layer, as shown in FIG. 4. Alternatively, the insulating layer 1a may be formed by only the build-up layer 12 without a core layer, as shown in FIG. 5.

The core layer 11 is a layer that becomes the core of target substrate 1. A through hole and the like 11a may be formed in the core layer 11.

The build-up layer 12 is a layer built up in the target substrate 1. The build-up layer 12 may be formed as one layer, or may be formed as a plurality of layers. In the example shown in FIG. 2, three build-up layers 12 are formed on each of both surfaces of the core layer 11. In the example shown in FIG. 3, three build-up layers 12 are formed on one surface of the core layer 11. In the example shown in FIG. 5, three build-up layers 12 are formed. In the build-up layer 12, for example, a copper wiring 12a, a via 12b, a pad 12c, and the like are formed.

The conductor layer 1b is, for example, copper formed on the insulating layer 1a by electroless plating or sputtering.

The photosensitive layer 2 is formed on the conductor layer 1b of the target substrate 1. In addition, in a substrate of a semiconductor element mounted on a semiconductor package substrate, a photosensitive layer is formed not on a conductor layer but on an insulating layer, which is a silicon oxide film or a silicon nitride film.

The photosensitive layer 2 is a layer formed using a negative type photosensitive resin composition that is cured (photocured) by being irradiated with light. In addition, a positive type photosensitive resin composition is used for the substrate of the semiconductor element mounted on the semiconductor package substrate. The photosensitive resin composition that forms the photosensitive layer 2 contains, for example, a binder polymer such as a binder polymer having a carboxyl group, a photopolymerizable compound such as a radical polymerizable compound having an ethylenically unsaturated bond, and a photopolymerization initiator such as a photoradical polymerization initiator. The photosensitive resin composition that forms the photosensitive layer 2 may contain a photosensitizer, a polymerization inhibitor, or other components, as necessary. The photosensitive resin composition that forms the photosensitive layer 2 may contain, for example, dyes such as malachite green, Victoria Pure Blue, brilliant green, and methyl violet, photocoloring agents such as tribromophenyl sulfone, leuco crystal violet, diphenylamine, benzylamine, triphenylamine, diethylaniline and o-chloroaniline, thermal color inhibitors, plasticizers such as p-toluenesulfonamide, and additives such as pigments, fillers, defoamers, flame retardants, adhesion agents, leveling agents, peeling promoters, antioxidants, fragrances, imaging agents, and thermal crosslinking agents.

The support 3 may be formed by a resin film (support film). As a resin film forming the support 3, a polymer film having heat resistance and solvent resistance, such as a polyester such as polyethylene terephthalate (PET) or a polyolefin such as polypropylene or polyethylene, may be used. In addition, as a resin film forming the support 3, a film with a gas barrier property, such as polyvinyl alcohol (PVA), may be used. In addition, the resin film forming the support 3 may be a polymer film having heat resistance and solvent resistance, such as an acrylic resin or a styrene resin. In addition, the substrate of the semiconductor element mounted on the semiconductor package substrate does not have such a support (resin film).

As a method of forming the photosensitive layer 2 and the support 3 on the target substrate 1, for example, there is a method using a film-like photosensitive element (not shown). The film-like photosensitive element includes, for example, a support, a photosensitive layer, and a protective layer in this order. Then, by pressing the photosensitive layer of the photosensitive element onto the target substrate 1 while heating the photosensitive layer of the photosensitive element after removing the protective layer, the photosensitive layer 2 and the support 3 are formed on the target substrate 1. As a result, a laminate 4 including the target substrate 1, the photosensitive layer 2, the support 3, and the support film (not shown) in this order is obtained. In addition, an intermediate layer and the like may be arranged between the support 3 and the photosensitive layer 2. In addition, in the substrate of the semiconductor element mounted on the semiconductor package substrate, a liquid resist is used instead of the film-like photosensitive element. For this reason, there is no such support and protective layer, and a photosensitive layer is formed on a substrate by spin coating and post-baking.

### (Exposure Step)

As shown in FIG. 1(b), in the exposure step, the photosensitive layer 2 is exposed to actinic light through the support 3. As a result, an exposed portion irradiated with the actinic light is photocured, forming a photocured portion 2a (latent image). As the exposure method, a known exposure method can be applied, and examples thereof include a method of emitting actinic light in an image-like manner through a photomask 5 called artwork (mask exposure method), an LDI (laser direct imaging) exposure method, and a method of emitting light in an image-like manner through a lens using an actinic light by which an image of a photomask has been projected (projection exposure method). In addition, since the substrate of the semiconductor element mounted on the semiconductor package substrate does not have such a support, the photosensitive layer is exposed without a support. In addition, in the substrate of the semiconductor element mounted on the semiconductor package substrate, the projection exposure method is the mainstream as an exposure method for exposing the photosensitive layer, and the LDI exposure method is not used.

### (Development Step)

As shown in FIG. 1(c), in the development step, an uncured portion 2b of the photosensitive layer 2 is removed from the target substrate 1. By the development step, a resist pattern 6 formed by the photocured portion 2a obtained by photocuring the photosensitive layer 2 is formed on the target substrate 1. In addition, in the substrate of the semiconductor element mounted on the semiconductor package substrate, a positive type photosensitive resin composition is used as a photosensitive layer, so that the unexposed portion becomes a resist pattern.

The thickness of the resist pattern 6 formed on the target substrate 1 may be, for example, 3 μm or more, 5 μm or more, or 10 μm or more. Alternatively, the thickness of the resist pattern 6 formed on the target substrate 1 may be, for example, 200 μm or less, 100 μm or less, or 60 μm or less. The minimum and maximum values of the thickness of the resist pattern 6 can be appropriately combined. For example, the thickness of the resist pattern 6 formed on the target substrate 1 may be 3 μm or more and 200 μm or less, 5 μm or more and 100 μm or less, or 10 μm or more and 60 μm or less. The thickness of the resist pattern 6 is a height relative to the target substrate 1 in a direction perpendicular to the main surface of the target substrate 1.

### <Coordinate Measuring Step>

In the coordinate measuring step, the coordinates of the contour of the resist pattern formed on the target substrate are measured. In the coordinate measuring step, the coordinates of the contour of the pattern are measured based on, for example, reflected light from the target substrate, fluorescent light from the target substrate, or an electron beam from the target substrate.

Incidentally, in a semiconductor element mounted on a semiconductor package substrate, its substrate is formed of silicon, and a resist pattern is formed on the silicon oxide film or the silicon nitride film. For this reason, even if reflected light or fluorescent light from the substrate of the semiconductor element is detected, it is not possible to obtain, from the reflected light or the fluorescent light, a contrast between the substrate (silicon oxide film or silicon nitride film) and the resist pattern to the extent that the boundary between the substrate and the resist pattern can be identified. Therefore, it is extremely difficult and impractical to detect the coordinates of the contour of the resist pattern formed on the substrate of the semiconductor element based on the reflected light or fluorescent light from the substrate of the semiconductor element. On the other hand, in the target substrate 1, the resist pattern 6 is formed on the conductor layer 1b formed of copper or the like. For this reason, when reflected light or fluorescent light from the target substrate 1 is detected, it is possible to obtain, from the reflected light or the fluorescent light, a contrast between the substrate (conductor layer 1b) and the resist pattern 6 to the extent that the boundary between the substrate and the resist pattern 6 can be identified. Therefore, it is possible to detect the coordinates of the resist pattern 6 formed on the target substrate 1 based on the reflected light or fluorescent light from the target substrate 1.

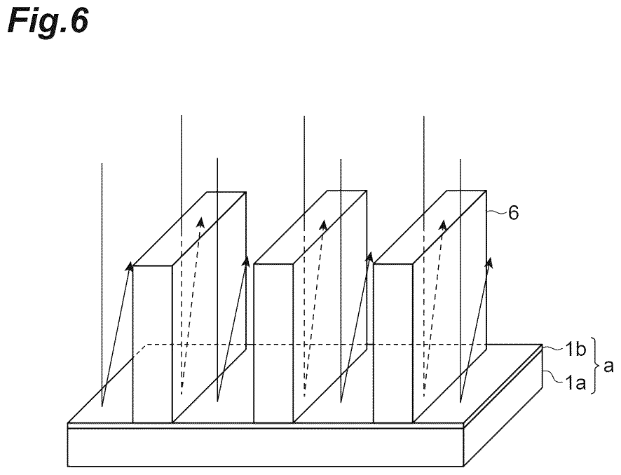

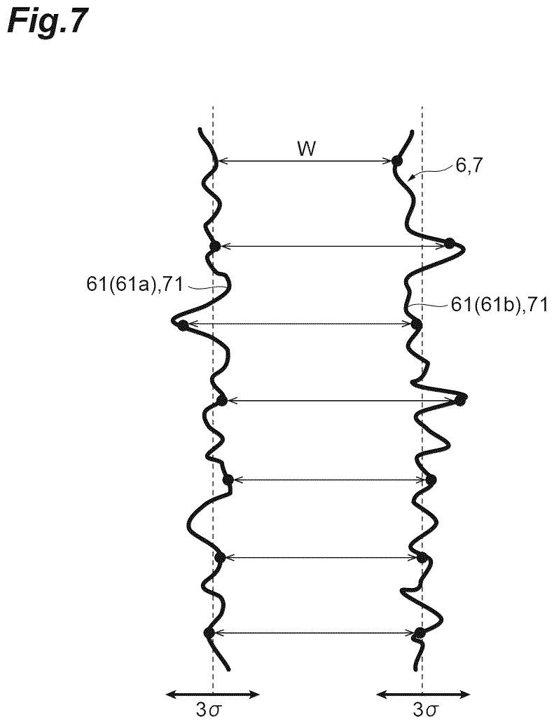

FIG. 6 shows, as an example of the coordinate measuring step, a case in which the coordinates of a contour 61 (see FIG. 7) of the resist pattern 6 are measured based on reflected light from the target substrate 1. As shown in FIG. 6, when measuring the coordinates of the contour 61 of the resist pattern 6 based on reflected light from the target substrate 1, first, inspection light is emitted to the target substrate 1 on which the resist pattern 6 is formed, and reflected light from the target substrate 1 is received. The wavelength of the inspection light may be, for example, 380 nm or more, 430 nm or more, or 600 nm or more. Alternatively, the wavelength of the inspection light may be, for example, 830 nm or less, 780 nm or less, or 700 nm or less. The minimum and maximum values of the wavelength can be appropriately combined. For example, the wavelength of the inspection light may be 380 nm or more and 830 nm or less, 430 nm or more and 780 nm or less, or 600 nm or more and 700 nm or less. In addition, as the inspection light, white light using a laser excitation light source or the like may be used. The light receiving area of the target substrate 1 that receives reflected light in the coordinate measuring step may be, for example, 100 μm² to 2500 cm², 500 μm² to 1200 cm², or 1000 μm² to 600 cm². The light receiving area is also an area where inspection light is emitted onto the target substrate 1 in a single measurement. In the inspection light emission method, for example, either specular reflected light or diffuse reflected light may be used, or a combination of specular reflected light and diffuse reflected light may be used.

Then, based on the contrast between the reflected light from the resist pattern 6 and the reflected light from the area other than the resist pattern 6, the contour 61 of the resist pattern 6 is identified. For example, in a received image of reflected light, a boundary where contrast in brightness, chromaticity, or the like increases is detected. Then, this detected boundary is identified as the contour 61 of the resist pattern 6, and the coordinates of the identified contour 61 are measured. The coordinates of the contour 61 to be measured are those of the X-Y coordinate system (two-axes coordinate system) on the main surface of the target substrate 1. Then, in measuring the coordinates of the contour 61, the coordinates of the contour 61 at a plurality of measurement points are measured. In order to identify the contour 61 of the resist pattern 6 and measure the coordinates of the contour 61 based on the reflected light from the target substrate 1, for example, a computer numerical control image measurement system such as NEXIV VMZ-R4540 (manufactured by NIKON CORPORATION, product name) or OPTELICS HYBRID+ (manufactured by Lasertec Corporation, product name) can be used.

When measuring the coordinates of the contour 61 of the resist pattern 6 based on the fluorescent light from the target substrate 1, the contour 61 of the resist pattern 6 is identified based on the contrast between the fluorescent light from the resist pattern 6 and the fluorescent light from the area other than the resist pattern 6, similarly to the case of measuring the coordinates of the contour 61 of the resist pattern 6 based on the reflected light from the target substrate 1, for example. Then, the coordinates of the identified contour 61 are measured. Whose coordinates are to be measured of the contour 61 of the resist pattern 6 based on the fluorescent light from the target substrate 1, a fluorescent microscope such as ECLIPS L300N (manufactured by NIKON CORPORATION, product name) can be used.

When measuring the coordinates of the contour 61 of the resist pattern 6 based on the electron beam from the target substrate 1, the contour 61 of the resist pattern 6 is identified based on the contrast between the electron beam from the resist pattern 6 and the electron beam from the area other than the resist pattern 6, similarly to the case of measuring the coordinates of the contour 61 of the resist pattern 6 based on the reflected light from the target substrate 1, for example. Then, the coordinates of the identified contour 61 are measured. Whose coordinates are to be measured of the contour 61 of the resist pattern 6 based on the electron beam from the target substrate 1, a CD-SEM (Critical Dimension Scanning Electron Microscope) such as CS4800 (manufactured by Hitachi High-Tech Corporation, product name) can be used.

The number of measurement points, the distance between measurement points, and the like on the contour 61 whose coordinates are to be measured are not particularly limited. However, from the viewpoint that the resist pattern 6 can be evaluated with high accuracy, the more measurement points on the contour 61 whose coordinates are to be measured, the better. In addition, the smaller the distance between measurement points on the contour 61 whose coordinates are to be measured, the better. From this viewpoint, for example, the distance between measurement points on the contour 61 whose coordinates are to be measured may be 0.5 μm or less, 0.3 μm or less, or 0.2 μm or less. On the other hand, if there are too many measurement points on the contour 61 whose coordinates are to be measured, and if the distance between measurement points on the contour 61 whose coordinates are to be measured is too small, it takes too much time whose coordinates are to be measured of the contour 61. From this viewpoint, for example, the distance between measurement points on the contour 61 whose coordinates are to be measured may be 0.001 μm or more, 0.005 μm or more, or 0.01 μm or more. The minimum and maximum values of the distance between measurement points can be appropriately combined. For example, the distance between measurement points on the contour 61 whose coordinates are to be measured may be 0.001 μm or more and 0.5 μm or less, 0.005 μm or more and 0.3 μm or less, or 0.01 μm or more and 0.2 μm or less.

### <Inspection Step>

In the inspection step, the resist pattern is inspected based on the coordinates measured in the coordinate measuring step.

Here, the resist pattern formed on the target substrate will be described in detail. As shown in FIG. 7, the resist pattern 6 formed on the target substrate 1 has a certain degree of roughness. That is, a contour 61a on one side of the resist pattern 6 and a contour 61b on the other side of the resist pattern 6 do not extend in a completely straight line or curved shape in the extension direction of the resist pattern 6, but rather often extend in the extension direction of the resist pattern 6 while fluctuating (being uneven) in the width direction of the resist pattern 6. As a result, the contour 61 (the contour 61a on one side or the contour 61b on the other side) of the resist pattern 6 becomes rough, and the line width W of the resist pattern 6 varies. Therefore, in the inspection step, the roughness of the resist pattern 6 is inspected based on the coordinates measured in the coordinate measuring step.

For inspection of the resist pattern 6, for example, calculation of the variation in the contour 61 of the resist pattern 6, calculation of the line width W of the resist pattern 6 and the variation in the line width W, and comparison with pattern data for forming the resist pattern 6 are performed.

In calculating the variation in the contour 61 of the resist pattern 6, the variation in the contour 61 of the resist pattern 6 in the width direction of the resist pattern 6 is calculated from the coordinates of the contour 61 at a plurality of measurement points measured in the coordinate measuring step. As the variation in the contour 61 of the resist pattern 6, for example, 3σ of the contour 61 of the resist pattern 6 is calculated based on the coordinates of the contour 61 of the resist pattern 6 measured in the coordinate measuring step. That is, 3σ of the contour 61 of the resist pattern 6 is calculated from the coordinates of the contour 61 at the plurality of measurement points measured in the coordinate measuring step. σ is a standard deviation, and 3σ is also called a detection limit. 3σ of the contour 61 of the resist pattern 6 is also called LER (Line Edge Roughness).

In calculating the line width W of the resist pattern 6 and the variation in the line width W, the line width W of the resist pattern 6 at a plurality of positions is calculated from the coordinates of the contour 61 at a plurality of measurement points measured in the coordinate measuring step. Then, from the plurality of calculated line widths W, the variation in the line width W of the resist pattern 6 in the width direction of the resist pattern 6 is calculated. As the variation in the line width W of the resist pattern 6, for example, 3σ of the line width W of the resist pattern 6 is calculated based on the coordinates of the contour 61 of the resist pattern 6 measured in the coordinate measuring step. That is, the line width W of the resist pattern 6 at a plurality of positions is calculated from the coordinates of the contour 61 at the plurality of measurement points measured in the coordinate measuring step. Then, from the plurality of calculated line widths W, 3σ of the line width W of the resist pattern 6 is calculated. 3σ of the line width W of the resist pattern 6 is also called LWR (Line Width Roughness). In addition, the resist pattern 6 and the space (gap between the resist patterns 6 adjacent to each other) can be distinguished, for example, by comparison with pattern data for forming the resist pattern 6, differences in the brightness of the reflected light from the target substrate 1, and the like.

In comparison with the pattern data for forming the resist pattern 6, for example, a plurality of measurement points on the contour 61 of the resist pattern 6 measured in the coordinate measuring step are plotted from the coordinates of the contour 61 of the resist pattern 6 at a plurality of measurement points measured in the coordinate measuring step. Then, the line formed by this plot is compared with the pattern data for forming the resist pattern 6, and from the comparison result, defects in the resist pattern 6 are detected and the number of detected defects is calculated.

### [Conductor Pattern Inspection Method]

A conductor pattern inspection method includes a coordinate measuring step for measuring the coordinates of the contour of a conductor pattern formed on a target substrate and an inspection step for inspecting conductor pattern based on the coordinates measured in the coordinate measuring step. The conductor pattern inspection method may include a conductor pattern forming step for forming a conductor pattern on a target substrate, on which a resist pattern is formed, by performing etching processing or plating processing on the target substrate, before the coordinate measuring step. In addition, the conductor pattern inspection method may include other steps.

### <Coordinate Measuring Step>

In the coordinate measuring step, the coordinates of the contour of the conductor pattern formed on the target substrate are measured. The coordinate measuring step of the conductor pattern inspection method can be performed, for example, similarly to the coordinate measuring step of the resist pattern inspection method. That is, the coordinate measuring step of the conductor pattern inspection method can be performed by replacing the resist pattern (resist pattern 6) and the contour (contour 61) with the conductor pattern (conductor pattern 7) and the contour (contour 71) in the coordinate measuring step of the resist pattern inspection method.

In addition, performing etching processing on the target substrate reduces the line width of the conductor pattern. For this reason, when inspecting the conductor pattern by comparison with pattern data for forming the conductor pattern 7 after performing etching processing on the target substrate, for example, the conductor pattern may be inspected by comparison with pattern data for forming the conductor pattern considering that the etching processing reduces the line width of the conductor pattern.

### <Inspection Step>

In the inspection step, the conductor pattern is inspected based on the coordinates measured in the coordinate measuring step. The inspection step of the conductor pattern inspection method can be performed, for example, similarly to the inspection step of the resist pattern inspection method. That is, the inspection step of the conductor pattern inspection method can be performed by replacing the resist pattern (resist pattern 6) and the contour (contour 61) with the conductor pattern (conductor pattern 7) and the contour (contour 71) in the inspection step of the resist pattern inspection method.

### [Resist Pattern Manufacturing Method]

A resist pattern manufacturing method according to an embodiment includes a resist pattern forming step for forming a resist pattern on a target substrate, a coordinate measuring step for measuring the coordinates of the contour of the resist pattern on the target substrate after the resist pattern forming step, and an inspection step for inspecting the resist pattern based on the coordinates measured in the coordinate measuring step. The resist pattern forming step of the resist pattern manufacturing method may be the same as the resist pattern forming step of the resist pattern inspection method described above, for example. In addition, the coordinate measuring step of the resist pattern manufacturing method may be the same as the coordinate measuring step of the resist pattern inspection method described above, for example. For this reason, in the coordinate measuring step of the resist pattern manufacturing method, for example, similarly to the coordinate measuring step of the resist pattern inspection method described above, the coordinates of the contour of the pattern are measured based on the reflected light from the target substrate, the fluorescent light from the target substrate, or the electron beam from the target substrate. In addition, the inspection step of the resist pattern manufacturing method may be the same as the inspection step of the resist pattern inspection method described above, for example. The resist pattern manufacturing method may include other steps.

### [Target Substrate Selection Method]

The target substrate selection method according to the present embodiment is a selection method for selecting a target substrate on which patterns are formed. This target substrate selection method is a target substrate selection method based on a resist pattern, which selects a target substrate on which a resist pattern is formed, and a target substrate selection method based on a conductor pattern, which selects a target substrate on which a conductor pattern is formed.

### [Target Substrate Selection Method Based on Resist Pattern]

The target substrate selection method based on the resist pattern includes a coordinate measuring step for measuring the coordinates of the contour of the resist pattern formed on the target substrate, an inspection step for inspecting the resist pattern based on the coordinates measured in the coordinate measuring step, and an evaluation step for evaluating the resist pattern based on the inspection result in the inspection step. The coordinate measuring step of the target substrate selection method based on the resist pattern may be the same as the coordinate measuring step of the resist pattern inspection method described above, for example. The inspection step of the target substrate selection method based on the resist pattern may be the same as the inspection step of the resist pattern inspection method described above, for example. The target substrate selection method based on the resist pattern may include other steps.

### <Evaluation Step>

In the evaluation step, the resist pattern is evaluated based on the inspection result in the inspection step.

As shown in FIG. 7, for example, when the roughness of the resist pattern 6 is inspected based on the coordinates of the contour 61 of the resist pattern 6 measured in the coordinate measuring step as an inspection for the resist pattern 6 in the inspection step, the resist pattern 6 is evaluated based on the roughness of the resist pattern 6 in the evaluation step.

In addition, for example, when the variation in the contour 61 of the resist pattern 6 is calculated based on the coordinates of the contour 61 of the resist pattern 6 measured in the coordinate measuring step as an inspection for the resist pattern 6 in the inspection step, the resist pattern 6 is evaluated based on the degree of variation in the contour 61 in the evaluation step. That is, if the degree of variation in the contour 61 falls below a reference, a good evaluation is obtained, and if the degree of variation in the contour 61 exceeds the reference, a bad evaluation is obtained. For example, when 3σ of the contour 61 of the resist pattern 6 is calculated as the variation in the contour 61 of the resist pattern 6 in the inspection step, a good evaluation is obtained if 3σ of the contour 61 of the resist pattern 6 falls below a predetermined reference value and a bad evaluation is obtained if 3σ of the contour 61 of the resist pattern 6 exceeds the predetermined reference value in the evaluation step.

In addition, for example, when the variation in the line width W of the resist pattern 6 is calculated based on the coordinates of the contour 61 of the resist pattern 6 measured in the coordinate measuring step as an inspection for the resist pattern 6 in the inspection step, the resist pattern 6 is evaluated based on the degree of variation in the line width W in the evaluation step. That is, if the degree of variation in the line width W falls below a reference, a good evaluation is obtained, and if the degree of variation in the line width W1 exceeds the reference, a bad evaluation is obtained. For example, when 3σ of the line width W of the resist pattern 6 is calculated as the variation in the line width W of the resist pattern 6 in the inspection step, a good evaluation is obtained if 3σ of the line width W of the resist pattern 6 falls below a predetermined reference value and a bad evaluation is obtained if 3σ of the line width W of the resist pattern 6 exceeds the predetermined reference value in the evaluation step.

In addition, for example, when the coordinates of the contour 61 of the resist pattern 6 measured in the coordinate measuring step are compared with the pattern data for forming the resist pattern 6 as an inspection for the resist pattern 6 in the inspection step, the resist pattern 6 is evaluated based on the comparison result in the evaluation step. For example, when the number of defects in the resist pattern 6 is calculated by comparing the coordinates of the contour 61 of the resist pattern 6 measured in the coordinate measuring step with the pattern data for forming the resist pattern 6 as an inspection for the resist pattern 6 in the inspection step, a good evaluation is obtained if the number of defects in the resist pattern 6 falls below a predetermined reference value and a bad evaluation is obtained if the number of defects in the resist pattern 6 exceeds the predetermined reference value in the evaluation step.

### [Target Substrate Selection Method Based on Conductor Pattern]

The target substrate selection method based on a conductor pattern includes a coordinate measuring step for measuring the coordinates of the contour of the conductor pattern formed on the target substrate, an inspection step for inspecting the conductor pattern based on the coordinates measured in the coordinate measuring step, and an evaluation step for evaluating the conductor pattern based on the inspection result in the inspection step. The coordinate measuring step of the target substrate selection method based on the conductor pattern may be the same as the coordinate measuring step of the conductor pattern inspection method described above, for example. The inspection step of the target substrate selection method based on the conductor pattern may be the same as the inspection step of the conductor pattern inspection method described above, for example. The target substrate selection method based on the conductor pattern may include other steps.

### <Evaluation Step>

In the evaluation step, the conductor pattern is evaluated based on the inspection result in the inspection step. The evaluation step of the target substrate selection method based on the conductor pattern can be performed similarly to the evaluation step of the target substrate selection method based on the resist pattern, for example. That is, the evaluation step of the target substrate selection method based on the conductor pattern can be performed by replacing the resist pattern (resist pattern 6) and the contour (contour 61) with the conductor pattern (conductor pattern 7) and the contour (contour 71) in the evaluation step of the target substrate selection method based on the resist pattern.

### [Target Substrate Manufacturing Method]

A target substrate manufacturing method according to the present embodiment includes a conductor pattern forming step for forming a conductor pattern by performing etching processing or plating processing on the target substrate on which a resist pattern is formed, the resist pattern satisfying the resist pattern evaluation criteria in the target substrate selection method described above. That is, in the conductor pattern forming step, for a target substrate not satisfying the resist pattern evaluation criteria in the target substrate selection method among the target substrates on which resist patterns are formed, etching processing or plating processing is not performed to form a conductor pattern. An example of the case where the resist pattern evaluation criteria in the target substrate selection method are not satisfied is a case where a bad evaluation is obtained in the evaluation step. The target substrate manufacturing method according to the present embodiment may include other steps, such as a resist pattern removing step, as necessary.

In the etching processing, using a resist pattern formed on a target substrate having a conductor layer as a mask, the conductor layer of the target substrate that is not covered with the resist is etched away. After the etching processing, the resist is removed by removing the resist pattern 6 to form a conductor pattern.

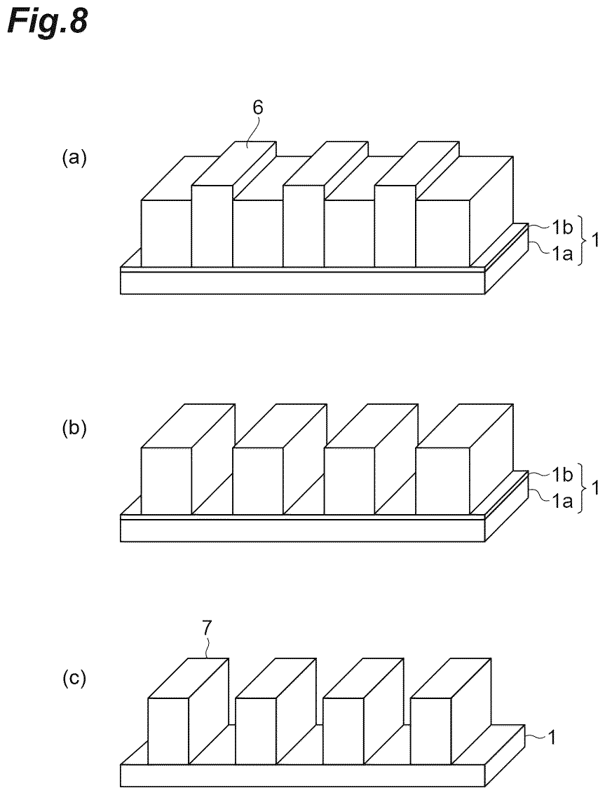

As shown in FIG. 8(a), in the plating process, using the resist pattern 6 formed on the target substrate 1 having the conductor layer 1b as a mask, copper, solder, or the like is plated on the conductor layer 1b of the target substrate 1 that is not covered with the resist. After the plating process, the resist is removed by removing the resist pattern 6 as shown in FIG. 8(b), and the conductor layer 1b covered with the resist is etched to form the conductor pattern 7 as shown in FIG. 8(c). As a plating method, electrolytic plating or electroless plating may be used. Between these, electrolytic plating may be used.

As described above, in the pattern inspection method according to the present embodiment, the coordinates of the contour 61 of the resist pattern 6 or the contour 71 of the conductor pattern 7 formed on the target substrate 1 are measured, and the resist pattern 6 or the conductor pattern 7 is inspected based on the measured coordinates. Therefore, even if the resist pattern 6 or the conductor pattern 7 formed on the target substrate 1 is made finer, the resist pattern 6 or the conductor pattern 7 can be evaluated. In addition, the resist pattern 6 or the conductor pattern 7 can be evaluated with higher accuracy than in the case of visual inspection.

In addition, in this pattern inspection method, as an inspection for the resist pattern 6 or the conductor pattern 7, the roughness of the resist pattern 6 or the conductor pattern 7 is calculated based on the coordinates of the contour 61 of the resist pattern 6 or the contour 71 of the conductor pattern 7. Therefore, the formation state of the resist pattern 6 or the conductor pattern 7 can be appropriately evaluated.

In addition, in this pattern inspection method, as an inspection for the resist pattern 6 or the conductor pattern 7, the variation in the contour 61 of the resist pattern 6 or the contour 71 of the conductor pattern 7 is calculated based on the measured coordinates of the contour 61 or the contour 71. Therefore, the formation state of the resist pattern 6 or the conductor pattern 7 can be appropriately evaluated.

In addition, in this pattern inspection method, as an inspection for the resist pattern 6 or the conductor pattern 7, the line width W and the variation in the line width W of the resist pattern 6 or the conductor pattern 7 are calculated based on the measured coordinates of the contour 61 or the contour 71. Therefore, the formation state of the resist pattern 6 or the conductor pattern 7 can be appropriately evaluated.

In addition, in this pattern inspection method, as an inspection for the resist pattern 6 or the conductor pattern 7, the measured coordinates of the contour 61 or the contour 71 are compared with the pattern data for forming the resist pattern 6 or the conductor pattern 7. Therefore, the formation state of the resist pattern 6 or the conductor pattern 7 can be evaluated with high accuracy.

In addition, in this pattern inspection method, the target substrate 1 contains an inorganic component containing at least one of silica filler and glass cloth, which are not used in substrates of semiconductor elements, and an organic component containing at least one of maleimide resin, bismaleimide-triazine resin, epoxy resin, phenolic resin, cyanate resin, isocyanate resin, benzoxazine resin, oxetane resin, amino resin, unsaturated polyester resin, allyl resin, dicyclopentadiene resin, triazine resin, melamine resin, and polyethylene terephthalate resin. For this reason, compared with the case of inspecting the pattern formed on the substrate of the semiconductor element, there are problems and difficulties such as distortion and warpage of the inspection target. However, by providing the above-described coordinate measuring step and inspection step, the resist pattern 6 or the conductor pattern 7 formed on the target substrate 1 can be evaluated.

In addition, in this pattern inspection method, the target substrate 1 has at least one of the core layer 11 and the build-up layer 12, unlike the structure of the substrate of the semiconductor element. For this reason, compared with the case of inspecting the pattern formed on the substrate of the semiconductor element, there are problems and difficulties such as distortion and warpage of the inspection target. However, by providing the above-described coordinate measuring step and inspection step, the pattern formed on the target substrate 1 can be evaluated.

In addition, in this pattern inspection method, the thickness of the target substrate 1 is 50 μm or more and 3000 μm or less, which is different from the thickness of the substrate of the semiconductor element. For this reason, compared with the case of inspecting the pattern formed on the substrate of the semiconductor element, there are problems and difficulties such as the focal position of the inspection target changing greatly depending on the observation point due to distortion and warpage of the inspection target and variations in the thickness of the inspection target, making difficult for the resist pattern and the conductor in focus. However, by providing the above-described coordinate measuring step and inspection step, the pattern formed on the target substrate 1 can be evaluated.

In addition, in this pattern inspection method, the resist pattern 6 formed on the target substrate 1 contains a binder polymer having a carboxyl group, a radical polymerizable compound having an ethylenically unsaturated bond, and a photoradical polymerization initiator, which are different from the resist pattern formed on the substrate of the semiconductor element. The substrate of the semiconductor element has no support and is thin. Therefore, when a binder polymer having a carboxyl group, a radical polymerizable compound having an ethylenically unsaturated bond, and a photoradical polymerization initiator are used in manufacturing the substrate of the semiconductor element, there are problems and difficulties such as the effect of oxygen in the exposure atmosphere inhibiting the curing of the resin, making it difficult to form a pattern. However, when the resist pattern 6 is formed on the target substrate 1, even if the resist pattern 6 contains a binder polymer having a carboxyl group, a radical polymerizable compound having an ethylenically unsaturated bond, and a photoradical polymerization initiator, the resist pattern 6 can be formed on the target substrate 1. Therefore, by providing the above-described coordinate measuring step and inspection step, the resist pattern 6 formed on the target substrate 1 can be evaluated.

In addition, in this pattern inspection method, the support 3, which is not provided on the resist pattern formed on the substrate of the semiconductor element and is formed of a resin film, is provided on the resist pattern 6, and the coordinates of the contour of the pattern are measured through this resin film. For this reason, compared with the case of inspecting the resist pattern formed on the substrate of the semiconductor element, there are problems and difficulties involved in inspecting the resist pattern 6 through a resin film. However, by providing the above-described coordinate measuring step and inspection step, the resist pattern 6 formed on the target substrate 1 can be evaluated.

In addition, in this pattern inspection method, the resist pattern 6 formed on the target substrate 1 is a pattern having a thickness of 3 μm or more and 200 μm or less, which is different from the resist pattern formed on the substrate of the semiconductor element. For this reason, compared with the case of inspecting the resist pattern formed on the substrate of the semiconductor element, there are problems and difficulties such as the detection contrast between the resist pattern and the substrate being likely to be low. However, by providing the above-described coordinate measuring step and inspection step, the resist pattern formed on the target substrate 1 can be evaluated.

In addition, in this pattern inspection method, the coordinates of the contour 61 of the resist pattern 6 or the contour 71 of the conductor pattern 7 are measured based on the reflected light from the target substrate 1. Therefore, it is possible to appropriately measure the coordinates of the contour 61 of the resist pattern 6 or the contour 71 of the conductor pattern 7 with high accuracy.

In addition, in this pattern inspection method, the coordinates of the contour 61 of the resist pattern 6 or the contour 71 of the conductor pattern 7 are measured based on the fluorescent light from the target substrate 1. Therefore, it is possible to appropriately measure the coordinates of the contour 61 of the resist pattern 6 or the contour 71 of the conductor pattern 7 with high accuracy.

In addition, in this pattern inspection method, the coordinates of the contour 61 of the resist pattern 6 or the contour 71 of the conductor pattern 7 are measured based on the electron beam from the target substrate 1. Therefore, it is possible to appropriately measure the coordinates of the contour 61 of the resist pattern 6 or the contour 71 of the conductor pattern 7 with high accuracy.

In the resist pattern manufacturing method according to the present embodiment, after the resist pattern 6 is formed on the target substrate 1, the coordinates of the contour 61 of the resist pattern 6 are measured, and the resist pattern 6 is inspected based on the measured coordinates. Therefore, even if the resist pattern 6 formed on the target substrate 1 is made finer, it is possible to evaluate the resist pattern 6. As a result, it is possible to manufacture the resist pattern 6 with a small degree of roughness.

In addition, in this resist pattern manufacturing method, the coordinates of the contour 61 of the resist pattern 6 are measured based on the reflected light from the target substrate 1, the fluorescent light from the target substrate 1, or the electron beam from the target substrate 1. Therefore, it is possible to appropriately measure the coordinates of the contour 61 of the resist pattern 6 with high accuracy.

In the target substrate selection method according to the present embodiment, the coordinates of the contour 61 of the resist pattern 6 or the contour 71 of the conductor pattern 7 formed on the target substrate 1 are measured, the resist pattern 6 or the conductor pattern 7 is inspected based on the measured coordinates, and the resist pattern 6 or the conductor pattern 7 is evaluated based on the inspection result. Therefore, the resist pattern 6 or the conductor pattern 7 can be evaluated with higher accuracy than in the case of visual inspection.

In addition, in this target substrate selection method according to the present embodiment, since the resist pattern 6 or the conductor pattern 7 is evaluated based on the roughness of the resist pattern 6 or the conductor pattern 7 calculated based on the measured coordinates of the contour 61 or contour 71, the formation state of the resist pattern 6 or the conductor pattern 7 can be appropriately evaluated.

In addition, in this target substrate selection method according to the present embodiment, since the resist pattern 6 or the conductor pattern 7 is evaluated based on the variation in the contour 61 or the contour 71 calculated based on the measured coordinates of the contour 61 or the contour 71, the formation state of the resist pattern 6 or the conductor pattern 7 can be appropriately evaluated.

In addition, in the target substrate selection method according to the present embodiment, since the resist pattern 6 or the conductor pattern 7 is evaluated based on the line width W and the variation in the line width W calculated based on the measured coordinates of the contour 61 or the contour 71, the formation state of the resist pattern 6 or the conductor pattern 7 can be appropriately evaluated.

In addition, in the target substrate selection method according to the present embodiment, since the resist pattern 6 or the conductor pattern 7 is evaluated based on the result of comparison between the measured coordinates of the contour 61 or the contour 71 and the pattern data for forming the resist pattern 6 or the conductor pattern 7, the formation state of the resist pattern 6 or the conductor pattern 7 can be appropriately evaluated.

In addition, in the target substrate selection method according to the present embodiment, by measuring the coordinates of the contour 61 of the resist pattern 6 or the contour 71 of the conductor pattern 7 based on the reflected light from the target substrate 1, the fluorescent light from the target substrate 1, or the electron beam from the target substrate 1, it is possible to appropriately measure the coordinates of the contour 61 of the resist pattern 6 or the contour 71 of the conductor pattern 7 with high accuracy.

In the target substrate manufacturing method according to the present embodiment, the conductor pattern 7 is formed by performing etching processing or plating processing on the target substrate 1 satisfying the criteria for the evaluation of the resist pattern 6 in the target substrate selection method described above, among the target substrates 1 on which the resist patterns 6 are formed. Therefore, it is possible to suppress the occurrence of defects such as defective formation of the conductor pattern 7 and degradation of the electrical characteristics of the manufactured semiconductor package.

The present disclosure is not limited to the above-described embodiments, and can be modified as appropriate without departing from the spirit of the present disclosure.

### EXAMPLES

Next, examples of the present disclosure will be described. However, the present disclosure is not limited to the following examples.

### Example 1

A substrate containing copper sputtered onto a polyethylene terephthalate film was heated to 80° C., and a photosensitive element was laminated (stacked) on the copper surface of the substrate. The lamination was performed by peeling a protective layer while bringing a photosensitive layer of the photosensitive element into contact with the copper surface of the substrate, using a heat roll at 110° C., at a pressing pressure of 0.4 MPa and a roll speed of 1.0 m/min. In this manner, a laminate having a substrate, a photosensitive layer, and a support in this order was obtained. The obtained laminate was used as a semiconductor package substrate for tests described below.

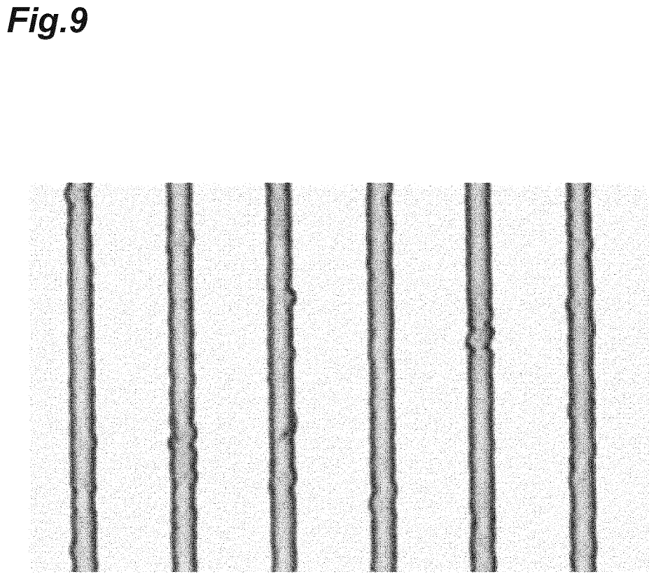

As Example 1, a resist pattern with L/S=3.0/7.0 μm was formed on a semiconductor package substrate. Then, the area of 73 μm×55 μm of the semiconductor package substrate was imaged using the NEXIV VMZ-R4540. FIG. 9 shows a photograph taken by the NEXIV VMZ-R4540.

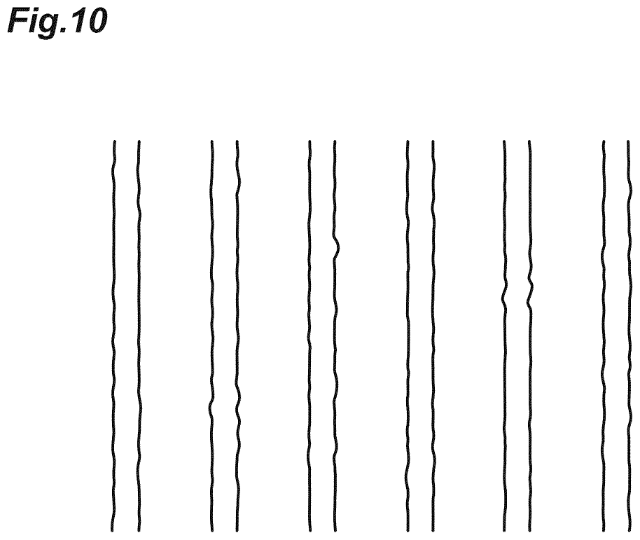

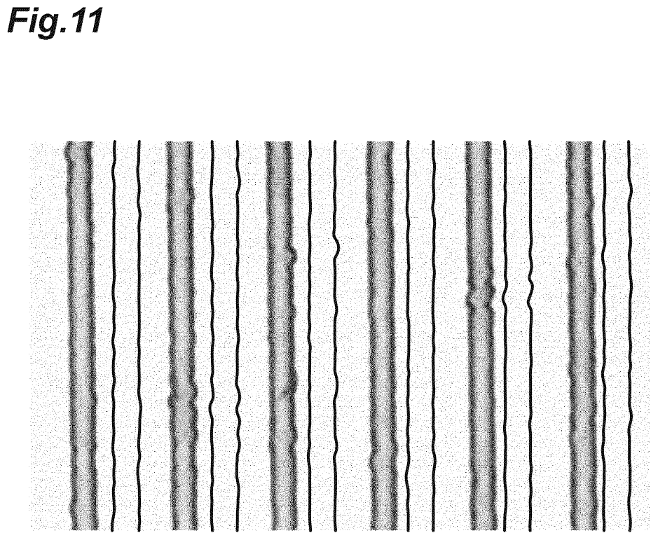

In addition, by scanning measurement using the NEXIV VMZ-R4540, the contour of the resist pattern on the semiconductor package substrate was identified, and the coordinates of the contour of the resist pattern were measured for six lines of the resist pattern. In measuring the coordinates, the coordinates of 260 points, each of which was spaced 0.2 μm apart over a length of 52 μm, were measured for each of the contour on one side and the contour on the other side of the line. In addition, these measurements were performed at three locations on each of the six lines. As a result, the coordinates of a total of 9360 points were measured. FIG. 10 shows a plot diagram in which the measured coordinates of the 3120 points are plotted. In addition, FIG. 11 is a diagram in which the plot diagram of FIG. 10 is superimposed on the photograph of FIG. 9 with a shift.

### (Consideration 1)

As shown in FIGS. 9 to 11, the plot diagrams on which the measured coordinates were plotted approximately matched the contour of the resist pattern in the photograph taken by the NEXIV VMZ-R4540. From these results, it was found that it is possible to inspect and evaluate the resist pattern based on the measured coordinates.

### Example 2

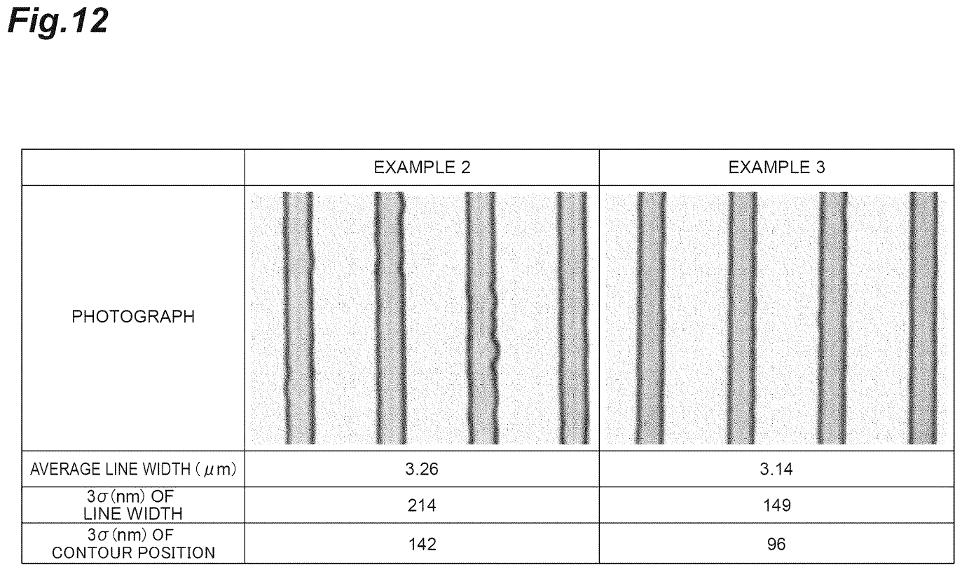

As Example 2, a resist pattern with L/S=3.0/7.0 μm was formed on a semiconductor package substrate. Then, the area of 73 μm×55 μm of the semiconductor package substrate was imaged using the NEXIV VMZ-R4540. FIG. 12 shows a photograph taken by the NEXIV VMZ-R4540.

In addition, by scanning measurement using the NEXIV VMZ-R4540, the contour of the resist pattern on the semiconductor package substrate was identified, and the coordinates of the contour of the resist pattern were measured for six lines. The measurement of the coordinates was performed in the same manner as in Example 1. Then, based on the measured coordinates of the 9360 points, the average line width of the resist pattern, the variation (3σ) in the line width of the resist pattern, and the variation (3σ) in the contour of the resist pattern were calculated. FIG. 12 shows the calculation results.

### Example 3

As Example 3, a resist pattern with L/S=3.0/7.0 μm was formed on a semiconductor package substrate. Then, the area of 73 μm×55 μm of the semiconductor package substrate was imaged using the NEXIV VMZ-R4540. FIG. 12 shows a photograph taken by the NEXIV VMZ-R4540.

In addition, by scanning measurement using the NEXIV VMZ-R4540, the contour of the resist pattern on the semiconductor package substrate was identified, and the coordinates of the contour of the resist pattern were measured for six lines. The measurement of the coordinates was performed in the same manner as in Example 1. Then, based on the measured coordinates of the 9360 points, the average line width of the resist pattern and the roughness of the resist pattern were calculated. As the roughness of the resist pattern, the variation (3σ) in the line width of the resist pattern and the variation (3σ) in the contour of the resist pattern were calculated. FIG. 12 shows the calculation results.

### (Consideration 2)

As shown in FIG. 12, from the photographs of Examples 2 and 3, it can be seen that the roughness of the resist pattern in Example 2 is larger than that in Example 3. In addition, the roughness of the resist pattern calculated based on the measured coordinates of the 9360 points is also larger in Example 2 than in Example 3. Specifically, the variation (3σ) in the line width of the resist pattern and the variation (3σ) in the contour of the resist pattern are both larger in Example 2 than in Example 3. From these results, it was found that the inspection and evaluation of the resist pattern based on the measured coordinates was appropriate. In addition, it was found that the roughness of the resist pattern could be quantified by inspecting the resist pattern based on the measured coordinates.

### INDUSTRIAL APPLICABILITY

The present disclosure can be used as a pattern inspection method, a resist pattern manufacturing method, a target substrate selection method, and a target substrate manufacturing method.

### REFERENCE SIGNS LIST

1: target substrate, 1a: insulating layer, 1b: conductor layer, 2: photosensitive layer, 2a: photocured portion, 2b: uncured portion, 3: support, 4: laminate, 5: photomask, 6: resist pattern, 61: contour, 61a: contour on one side, 61b: contour on the other side, 7: conductor pattern, 71: contour, W: line width.

1. A pattern inspection method for inspecting a pattern, which is either a resist pattern or a conductor pattern formed on a target substrate that is either a printed circuit board or a semiconductor package substrate for mounting of semiconductor elements, the method comprising:
a coordinate measuring step for measuring coordinates of a contour of the pattern; and
an inspection step for inspecting the pattern based on the measured coordinates.

2. The pattern inspection method according to claim 1,
wherein, in the inspection step, as the inspection of the pattern, a roughness of the pattern is calculated based on the measured coordinates.

3. The pattern inspection method according to claim 1,
wherein, in the inspection step, as the inspection of the pattern, a variation in a contour of the pattern is calculated based on the measured coordinates.

4. The pattern inspection method according to claim 1,
wherein, in the inspection step, as the inspection of the pattern, a line width of the pattern and a variation in the line width are calculated based on the measured coordinates.

5. The pattern inspection method according to claim 1,
wherein, in the inspection step, as the inspection of the pattern, the measured coordinates are compared with pattern data for forming the pattern.

6. The pattern inspection method according to claim 1,
wherein the target substrate contains an inorganic component containing at least one of silica filler and glass cloth and an organic component containing at least one of maleimide resin, bismaleimide-triazine resin, epoxy resin, phenolic resin, cyanate resin, isocyanate resin, benzoxazine resin, oxetane resin, amino resin, unsaturated polyester resin, allyl resin, dicyclopentadiene resin, triazine resin, melamine resin, and polyethylene terephthalate resin.

7. The pattern inspection method according to claim 1,
wherein the target substrate includes at least one of a core layer and a build-up layer.

8. The pattern inspection method according to claim 1,
wherein a thickness of the target substrate is 50 μm or more and 3000 μm or less.

9. The pattern inspection method according to claim 1,
wherein the pattern is the resist pattern, and
the resist pattern contains a binder polymer having a carboxyl group, a radical polymerizable compound having an ethylenically unsaturated bond, and a photoradical polymerization initiator.

10. The pattern inspection method according to claim 1,
wherein the pattern is the resist pattern,
a resin film is provided on the resist pattern, and
in the coordinate measuring step, the coordinates of the contour of the pattern are measured through the resin film.

11. The pattern inspection method according to claim 1,
wherein the pattern is the resist pattern, and
a thickness of the resist pattern is 3 μm or more and 200 μm or less.

12. The pattern inspection method according to claim 1,
wherein, in the coordinate measuring step, the coordinates of the contour of the pattern are measured based on reflected light from the target substrate.

13. The pattern inspection method according to claim 1,
wherein, in the coordinate measuring step, the coordinates of the contour of the pattern are measured based on fluorescent light from the target substrate.

14. The pattern inspection method according to claim 1,
wherein, in the coordinate measuring step, the coordinates of the contour of the pattern are measured based on an electron beam from the target substrate.

15. A resist pattern manufacturing method, comprising:
a resist pattern forming step for forming a resist pattern on a target substrate, which is either a printed circuit board or a semiconductor package substrate for mounting of semiconductor elements;
a coordinate measuring step for measuring coordinates of a contour of the resist pattern after the resist pattern forming step; and
an inspection step for inspecting the resist pattern based on the coordinates.

16. The resist pattern manufacturing method according to claim 15,
wherein, in the coordinate measuring step, the coordinates of the contour of the resist pattern are measured based on reflected light from the target substrate, fluorescent light from the target substrate, or an electron beam from the target substrate.

17. A target substrate selection method for selecting a target substrate, which is either a printed circuit board or a semiconductor package substrate for mounting of semiconductor elements, the method comprising:
a coordinate measuring step for measuring coordinates of a contour of a pattern, which is either a resist pattern or a conductor pattern formed on the target substrate;
an inspection step for inspecting the pattern based on the measured coordinates; and
an evaluation step for evaluating the pattern based on an inspection result in the inspection step.

18. The target substrate selection method according to claim 17,
wherein, in the inspection step, as the inspection of the pattern, a roughness of the pattern is calculated based on the measured coordinates, and
in the evaluation step, the pattern is evaluated based on the roughness of the pattern.

19. The target substrate selection method according to claim 17,
wherein, in the inspection step, as the inspection of the pattern, a variation in the contour is calculated based on the measured coordinates, and
in the evaluation step, the pattern is evaluated based on the variation in the contour.

20. The target substrate selection method according to claim 17,
wherein, in the inspection step, as the inspection of the pattern, a line width of the pattern and a variation in the line width are calculated based on the measured coordinates, and
in the evaluation step, the pattern is evaluated based on the calculated variation in the line width.

21. The target substrate selection method according to claim 17,
wherein, in the inspection step, as the inspection of the pattern, the measured coordinates are compared with pattern data for forming the pattern, and
in the evaluation step, the pattern is evaluated based on a result of comparison between the measured coordinates and the pattern data.

22. The target substrate selection method according to claim 17,
wherein, in the coordinate measuring step, the coordinates of the contour of the pattern are measured based on reflected light from the target substrate, fluorescent light from the target substrate, or an electron beam from the target substrate.

23. A target substrate manufacturing method, comprising:
a conductor pattern forming step for forming the conductor pattern by performing etching processing or plating processing on the target substrate on which the resist pattern is formed, the resist pattern satisfying criteria for the evaluation of the resist pattern in the target substrate selection method according to claim 17.
